(19) United States
(12) Patent Application Publication
(10) Pub. No.: US 2026/0307929 A1
(43) Pub. Date: Oct. 8, 2026

(54) FASTENING TAPE PEELING DEVICE

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 19/482,491

(22) PCT Filed: Jun. 27, 2023
(86) PCT No.: PCT/JP2023/023803

§ 371 Date: Nov. 7, 2025

(51) Int. Cl. B65H 35/00

(52) U.S. Cl. CPC B65H 35/0013; B65H 35/0073; B65H 2701/1942

(57) ABSTRACT

A fastening tape peeling device includes a support mechanism, a separating mechanism, a gripping mechanism, and a separation mechanism. The support mechanism rotatably supports a reel on which an outer peripheral portion of a spiral tape, around which a carrier tape is spirally wound, and a tip end portion of a cover tape are fastened by a fastening tape. The separating mechanism is configured to separate, from the outer peripheral portion of the spiral tape using air, a non-adhesive portion. The gripping mechanism grips the non-adhesive portion separated from the outer peripheral portion of the spiral tape by the separating mechanism. The separation mechanism separates the fastening tape from the cover tape by moving the gripping mechanism in a direction away from the reel in a state where the gripping mechanism grips the non-adhesive portion.

### TECHNICAL FIELD

The present description discloses a technique related to a fastening tape peeling device.

### BACKGROUND ART

A pre-use component tape recognition section described in Patent Literature 1 performs image processing on a captured result of a component reel and recognizes a tip end portion of a pre-use tape stored in the component reel. Further, a component tape setting processing section described in Patent Literature 1 causes a robot section and a pre-use tape holding tool based on a recognition result of the pre-use component tape recognition section to hold the tip end portion of the pre-use tape. Specifically, the tip end portion of the pre-use tape is gripped and held by a clip portion in the pre-use tape holding section.

### CITATION LIST

### Patent Literature

Patent Literature 1: JP 2019-204858 A

### BRIEF SUMMARY

### Technical Problem

A carrier tape is spirally wound around a reel. A tip end side of the carrier tape can be fastened to an outer peripheral portion of the spiral tape by a fastening tape. When the reel in which the tip end side of the carrier tape is fastened by the fastening tape is set in a feeder, it is necessary to peel the fastening tape. When a worker performs the peeling of the fastening tape, the number of work steps of the worker increases.

In view of such circumstances, the present description discloses a fastening tape peeling device capable of peeling a fastening tape of a reel.

### Solution to Problem

The present description discloses a fastening tape peeling device that includes a support mechanism, a separating mechanism, a gripping mechanism, and a separation mechanism. The support mechanism is configured to rotatably support a reel in which an outer peripheral portion of a spiral tape and a tip end portion of the cover tape are fastened by a fastening tape, a carrier tape being spirally wound in the spiral tape, the carrier tape including a base tape provided with an accommodation section that accommodates a component, and a cover tape that closes an accommodation section and is attached to the base tape. The separating mechanism is configured to separate, from the outer peripheral portion of the spiral tape using air, a non-adhesive portion which is a portion on a tip end side of the fastening tape of the reel supported by the support mechanism and in which an adhesive for fastening the fastening tape and the outer peripheral portion of the spiral tape is not provided. The gripping mechanism is configured to grip the non-adhesive portion separated from the outer peripheral portion of the spiral tape by the separating mechanism. The separation mechanism is configured to separate the fastening tape from the cover tape by moving the gripping mechanism in a direction away from the reel in a state where the gripping mechanism grips the non-adhesive portion.

### Advantageous Effects

According to the fastening tape peeling device described above, it is possible to separate the non-adhesive portion from the outer peripheral portion of the spiral tape using air and grip the separated non-adhesive portion to peel the fastening tape.

### BRIEF DESCRIPTION OF DRAWINGS

FIG. 1 is a perspective view illustrating an example of a setup device.

FIG. 2 is a plan view of the setup device of FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape of FIG. 4.

FIG. 6 is a flowchart illustrating an example of a control procedure by the setup device.

FIG. 7 is a schematic view illustrating an example of a tip end portion of the carrier tape.

FIG. 8 is a plan view illustrating an example of a fastening tape peeling device.

FIG. 9 is a flowchart illustrating an example of a control procedure by the fastening tape peeling device.

FIG. 10 is a perspective view illustrating an example of a support mechanism.

FIG. 11 is a side view of the support mechanism of FIG. 10.

FIG. 12 is a plan view illustrating an example of a rear surface of a reel.

FIG. 13 is a plan view illustrating an example of a state in which a non-adhesive portion of a fastening tape is gripped in the fastening tape peeling device of FIG. 8.

FIG. 14 is a plan view illustrating another example of a fastening tape peeling device.

### DESCRIPTION OF EMBODIMENTS

### 1. Embodiment

### 1-1. Configuration Example of Setup Device 10

Fastening tape peeling device 80 can be applied to, for example, setup device 10. Setup device 10 sets reel 70 on feeder 60 so that component 91 can be supplied from feeder 60. Setup device 10 need only set reel 70 on feeder 60, and may take various configurations.

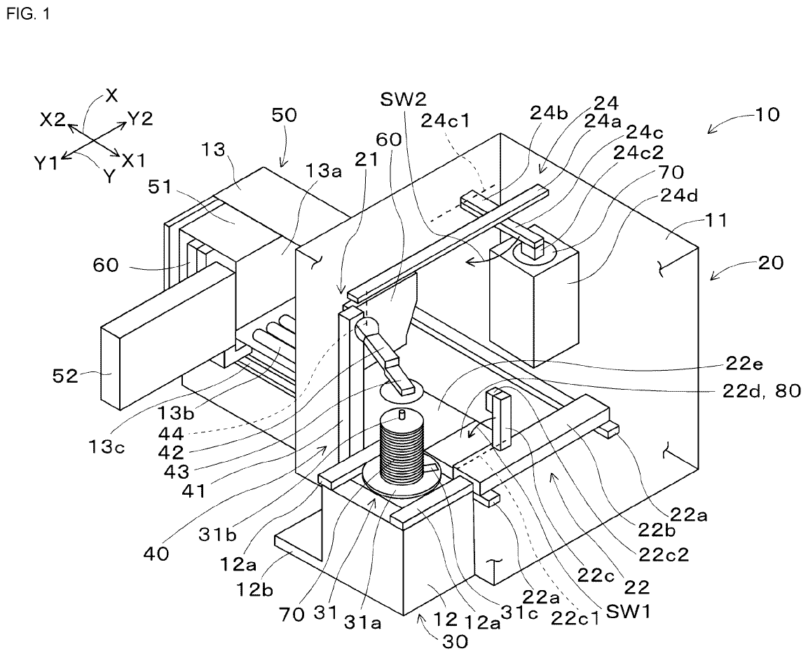

As illustrated in FIGS. 1 to 3, setup device 10 of an embodiment includes reel attachment/detachment section 20, reel supply section 30, reel transfer mechanism 40, and feeder supply section 50. For convenience of description, in the drawings, a facing direction between feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

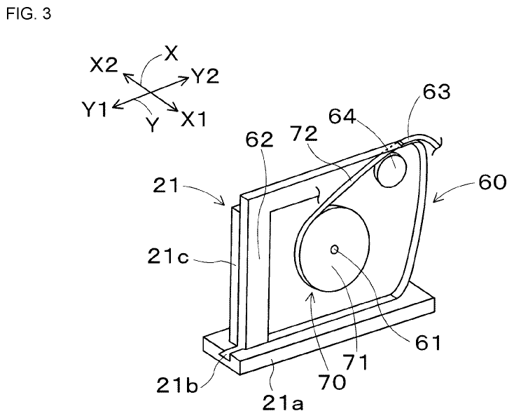

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and the second end side (arrow X2 direction) in the first direction and the first end side (arrow Y1 direction) in the second direction are partially opened. Reel supply section 30 is provided to be coupled to the first end side (arrow Y1 direction) in the second direction of reel attachment/detachment section 20. Reel supply section 30 is formed in box-shaped base 12 smaller than first housing 11. Reel transfer mechanism 40 is provided on plate base 12b extending from a bottom portion of base 12 to the second end side (arrow X2 direction) in the first direction. Feeder supply section 50 is provided to be coupled to the second end side (arrow X2 direction) in the first direction of reel attachment/detachment section 20. In feeder supply section 50, various members are assembled inside second housing 13 which is smaller than first housing 11 and has storage space 13a in an upper portion.

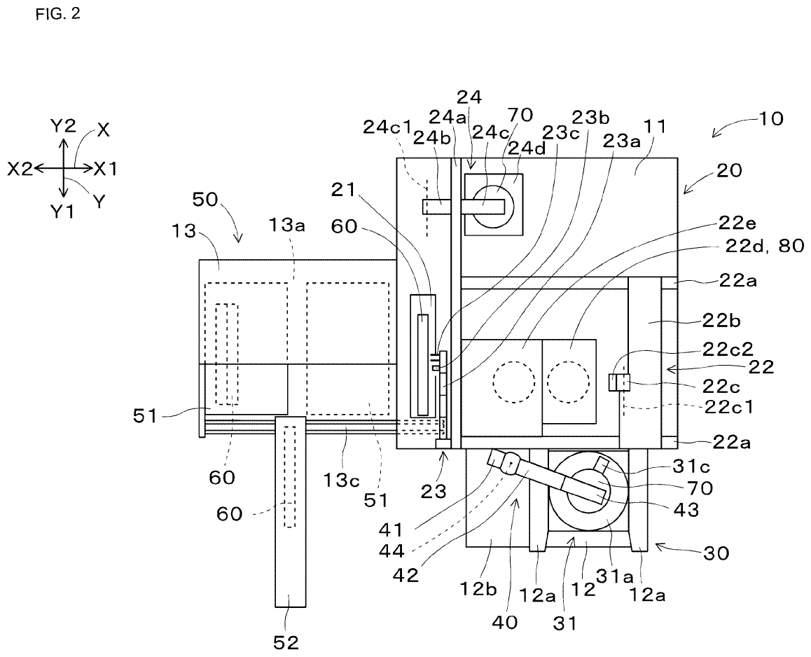

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from the first end side (arrow Y1 direction) in the second direction of slot 21b toward the second end side (arrow Y2 direction) in the second direction thereof, and is held at the work execution position. Support plate 21c is provided to stand up from bottom plate 21a, and comes into contact with the side surface of feeder 60 at the work execution position on the second end side (arrow X2 direction) in the first direction. Support plate 21c supports a pressing load to the second end side (arrow X2 direction) in the first direction generated when reel 70 is attached to feeder 60.

Feeder 60 is detachably provided on a component mounter. As illustrated in FIG. 3, feeder 60, to which reel 70 with carrier tape 72 wound around main body portion 71 is attached, conveys carrier tape 72 to supply component 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70.

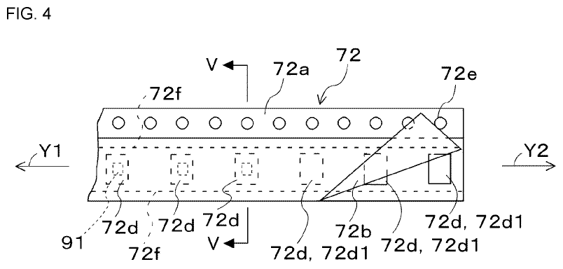

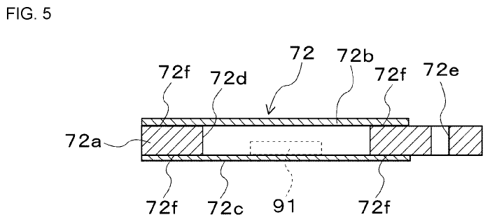

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Component 91 is accommodated in each of multiple accommodation sections 72d. As illustrated in FIG. 4, a predetermined number (for example, three in FIG. 4) of accommodation sections 72d from a tip end side of carrier tape 72 are empty accommodation sections 72d1 in which component 91 is not accommodated. Multiple accommodation sections 72d are provided at predetermined pitch intervals in a longitudinal direction of carrier tape 72 at the center portion in a width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at predetermined pitch intervals in the longitudinal direction of carrier tape 72 on the first end side in the width direction of base tape 72a. Cover tape 72b closes accommodation sections 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents component 91 accommodated in accommodation section 72d from falling off.

A center portion of side plate 62 on the first end side (arrow X1 direction) in the first direction of feeder 60 is open in order to facilitate attachment and detachment of reel 70. There are multiple types of reels 70 that are different in at least one of the material of carrier tape 72, the width dimension of carrier tape 72, and the width dimension of reel 70, and there are multiple types of feeders 60 corresponding to multiple types of reels 70. Feeder 60 includes collection position 63, sprocket 64, and a tape peeling section.

Collection position 63 is provided on a second end side (arrow Y2 direction) in the second direction of the upper surface of feeder 60, and the component mounter collects component 91 at collection position 63. Sprocket 64 is rotatably provided on the first end side (arrow Y1 direction) in the second direction with respect to collection position 63. The tooth portion of sprocket 64 engages with feed holes 72e of carrier tape 72. Sprocket 64 is intermittently driven by a drive motor and conveys carrier tape 72 at a constant pitch. The tape peeling section can peel off cover tape 72b from base tape 72a immediately before collection position 63 to enable taking out of component 91. After passing through collection position 63, carrier tape 72 is cut by a tape cutting device provided in the component mounter.

An identification code for identifying feeder 60 is given to each of feeders 60. Feeder 60 is provided with a feeder control section. The feeder control section stores the identification code of feeder 60 and the identification code of reel 70, and controls the component supply operation. When feeder 60 is held by feeder holding section 21, the connectors are fitted to each other, and the feeder control section is communicably connected to setup device 10.

Reel attachment mechanism 22 is provided on a first end side (arrow X1 direction) in the first direction of feeder holding section 21. Reel attachment mechanism 22 changes reel 70 in a horizontal posture to a vertical posture and attaches reel 70 to feeder 60 at the work execution position using reel transfer mechanism 40. Reel attachment mechanism 22 includes pair of guide rails 22a and 22a, moving table 22b, attachment member 22c, placement area 22d, and temporary placement area 22e. In reel attachment mechanism 22, a mechanism that changes reel 70 in the horizontal posture to the vertical posture and a mechanism that attaches reel 70 in the vertical posture to feeder 60 may be separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper sides of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment member 22c is formed in a square bar shape, and is provided to extend upward from moving table 22b. Attachment member 22c faces reel holding shaft 61 of feeder 60 at the work execution position. Specifically, attachment member 22c is provided at a position separated by a predetermined distance from a tip end portion of reel holding shaft 61 toward the first end side (arrow X1 direction) in the first direction. Attachment member 22c swings (arrow SW1 in FIG. 1) between an upright posture illustrated in FIGS. 1 and 2 and a horizontal posture in which attachment member 22c is tilted toward the second end side (arrow X2 direction) in the first direction around swing shaft 22c1 provided on moving table 22b side. Collection section 22c2 is provided on an end portion on a side different from an end portion of swing shaft 22c1 side of attachment member 22c. Collection section 22c2 detachably collects reel 70. As collection section 22c2, a claw portion inserted into the center hole of reel 70, a gripping mechanism that grips a peripheral edge of reel 70, a suction mechanism that picks up reel 70 by suction using negative pressure, or the like can be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area where multiple reels 70 can be temporarily placed is secured. Moving table 22b and attachment member 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot can be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at a tip end portion of articulated arm 23a. Camera 23b captures an image of feeder 60 at the work execution position to detect the positions and the states of reel 70 and carrier tape 72. Multiple fingers 23c are provided side by side with camera 23b at the tip end portion of articulated arm 23a. Multiple fingers 23c can perform a moving operation, a twisting operation, and the like in addition to the operation of gripping and releasing a work target.

Multiple fingers 23c load carrier tape 72 so that feed hole 72e at a tip end portion of carrier tape 72 engages with sprocket 64, thereby bringing carrier tape 72 into a feedable state. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on the first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment member 24c, and retrieval box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between feeder holding section 21 and a standby position provided on the second end side (arrow Y2 direction) in the second direction.

Detachment member 24c is formed of a thick plate-shaped member longer than moving table 24b, and is provided to extend along the first direction (arrow X direction) below moving table 24b. Detachment member 24c swings (arrow SW2 in FIG. 1) between a horizontal posture illustrated in FIGS. 1 and 2 and a vertical posture in which detachment member 24c is tilted downward around swing shaft 24cl provided on the second end side (arrow X2 direction) in the first direction of moving table 24b. Collection section 24c2 is provided on an end portion on a side different from the end portion on swing shaft 24c1 side of detachment member 24c. Collection section 24c2 detachably collects reel 70. The collecting method of collection section 24c2 may be the same as or different from collection section 22c2 of reel attachment mechanism 22.

Retrieval box 24d is provided to be positioned below detachment member 24c when moving table 24b is moved to the standby position. Retrieval box 24d retrieves multiple detached reels 70. Retrieval box 24d is formed in a box shape opening upward. Accordingly, retrieval box 24d can retrieve reels 70 that fall when collection section 24c2 of detachment member 24c releases reels 70.

Reel supply section 30 includes reel holding section 31 that is detachably provided. Pair of guide plates 12a and 12a extending along the second direction (arrow Y direction) is provided on the first end side (arrow X1 direction) in the first direction and the second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Reels 70 are not limited to unused reels, and may be reels in use in which carrier tape 72 has been used halfway. Reel holding section 31 includes circular plate-shaped holding plate 31a provided horizontally, and round rod-shaped holding shaft 31b provided upward from the center of holding plate 31a and penetrating through the center holes of reels 70. Accordingly, reel holding section 31 can hold multiple reels 70 in a state where holding shaft 31b penetrates through the center holes of multiple reels 70 even when reels 70 having at least one of different diameter and different width dimension coexist, and reels 70 can be easily taken out. Identification code 31c is attached to an upper surface of holding plate 31a. Identification code 31c includes information for specifying reel holding section 31.

For example, a worker procures multiple reels 70 based on work instruction data, and performs a stacking work of stacking multiple reels 70 on reel holding section 31. The work instruction data indicates a work content of the setup work performed by setup device 10. That is, in the work instruction data, type information of multiple reels 70 required with the progress of the production of the board product by the component mounter is associated with type information of multiple feeders 60 applicable to reels 70. A known automated guided vehicle or the like can also be used to convey multiple reels 70.

Reel transfer mechanism 40 is provided on plate base 12b extending from a bottom portion of base 12 to the second end side (arrow X2 direction) in the first direction. Reel transfer mechanism 40 includes support column 41, arm 42, and collection section 43. Support column 41 stands upward in the vertical direction on the second end side (arrow Y2 direction) in the second direction of plate base 12b. Arm 42 is provided to be liftable and lowerable with respect to support column 41. Further, arm 42 is rotatably provided on a horizontal plane around rotation axis 44 close to support column 41.

Collection section 43 is provided to be extendable and contractible with respect to arm 42. Collection section 43 detachably collects reel 70. The collecting method of collection section 43 may be the same as or different from the collecting method of collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 subsequently uses multiple reels 70 stacked on reel holding section 31 from the uppermost portion.

Feeder supply section 50 includes feeder accommodation section 51, which is detachably provided, and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along the first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10.

An identification code for identifying feeder accommodation section 51 is given to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used for conveying multiple feeders 60.

Guide rail 13c is provided in a lower portion on the first end side (arrow Y1 direction) in the second direction of storage space 13a of second housing 13. Guide rail 13c is provided in storage space 13a over substantially the entire first direction (arrow X direction), and is provided to extend to the first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that conveys feeder 60 into the built-in space through the opening portion or conveys feeder 60 out of the built-in space. Accordingly, feeder conveyance section 52 can convey feeder 60 out of feeder accommodation section 51 and feeder holding section 21, and can convey feeder 60 into feeder accommodation section 51 and feeder holding section 21. An openable and closable safety fence is provided on the first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10

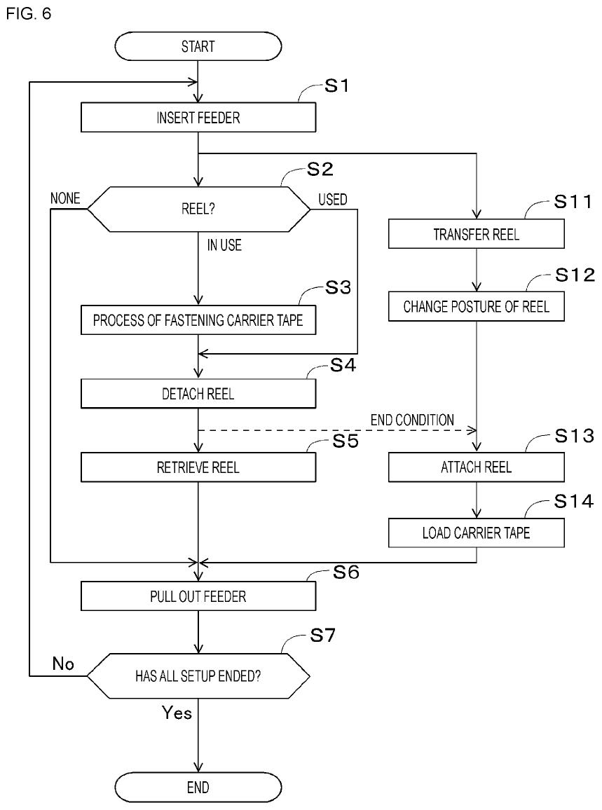

Setup device 10 causes feeder conveyance section 52 to convey feeder 60 corresponding to uppermost reel 70 of reel holding section 31 (step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The placement described above is repeated until applicable feeder 60 is present, and feeder 60 corresponding to uppermost reel 70 of reel holding section 31 is inserted into feeder holding section 21. After the control illustrated in step S1, in setup device 10, a first-series control illustrated in steps S2 to S5 and a second-series control illustrated in steps S11 to S14 are executed in parallel.

In the first-series control, setup device 10 checks the state of reel 70 based on the read identification code of feeder 60 or the read identification code of reel 70, and changes the control according to the state of reel 70 (step S2). Specifically, when feeder 60 is used in the component mounter in advance, there is a possibility that reel 70 in use in which carrier tape 72 has been used halfway is provided in feeder 60. In this case, tape loading mechanism 23 performs a fastening process of fastening the tip end portion of carrier tape 72 with a tape or the like to suppress slack of carrier tape 72 (step S3). At this time, tape loading mechanism 23 can wind carrier tape 72 onto reel 70 as necessary. Thereafter, tape loading mechanism 23 takes a retracted posture in which articulated arm 23a is bent.

Next, reel detachment mechanism 24 detaches reel 70 from feeder 60 (step S4). Specifically, moving table 24b moves from the standby position to feeder holding section 21. Then, when detachment member 24c is swung from the horizontal posture to the vertical posture, collection section 24c2 comes into contact with reel 70 and collects reel 70. Then, when detachment member 24c returns from the vertical posture to the horizontal posture, collection section 24c2 pulls out reel 70 from reel holding shaft 61 and holds reel 70 in the horizontal posture. At this time, setup device 10 deletes the identification code of reel 70 from the storage section of the feeder control section of feeder 60. Further, setup device 10 transmits the identification code of feeder 60, from which reel 70 has been detached, to a higher-level management device. At this time, setup device 10 may transmit the identification code of detached reel 70 together with the identification code of feeder 60 to the higher-level management device.

Next, reel detachment mechanism 24 retrieves reel 70 (step S5). Specifically, first, moving table 24b moves from feeder holding section 21 to the standby position. Then, collection section 24c2 releases reel 70. Thus, released reel 70 falls into retrieval box 24d and is retrieved. When reel 70 is retrieved, the first-series control is in a standby state until the second-series control ends.

There is a possibility that feeder 60 is provided with used reel 70 in which carrier tape 72 has been completely used (step S2). In this case, in the first-series control, the control illustrated in step S3 is omitted, and the controls illustrated in step S4 and step S5 are executed. There is a possibility that feeder 60 is not provided with reel 70 (step S2). In this case, in the first-series control, the controls illustrated in steps S3 to S5 are omitted.

In the second-series control, reel transfer mechanism 40 collects uppermost reel 70 of reel holding section 31 using collection section 43, and places reel 70 in placement area 22d (step S11). Then, reel transfer mechanism 40 returns collection section 43 to a position above reel holding section 31. When there is no applicable feeder 60, reel transfer mechanism 40 places reel 70 in temporary placement area 22e.

Next, reel attachment mechanism 22 changes the posture of reel 70 in placement area 22d (step S12). Specifically, first, attachment member 22c is changed from the upright posture to the horizontal posture, and collection section 22c2 comes into contact with reel 70 and collects reel 70. Then, attachment member 22c is returned from the horizontal posture to the upright posture, and collection section 22c2 changes reel 70 from the horizontal posture to the vertical posture and holds reel 70. It should be noted that when reel 70 in temporary placement area 22e is used, moving table 22b moves to the second end side (arrow X2 direction) in the first direction by a predetermined distance before attachment member 22c shifts from the upright posture to the horizontal posture. The second-series control is in a standby state until an end condition indicating the completion of the control of step S4 of the first-series is satisfied. This avoids interference between reel attachment mechanism 22 and reel detachment mechanism 24.

When the end condition described above is satisfied, reel attachment mechanism 22 attaches reel 70 to feeder 60 (step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10 stores the identification code of reel 70 in the feeder control section of feeder 60 to which reel 70 is attached. Further, setup device 10 transmits the identification code of feeder 60 and the identification code of reel 70 mounted on feeder 60 to the higher-level management device in association with each other. Moving table 22b returns to the standby position. Next, tape loading mechanism 23 loads carrier tape 72 until feed holes 72e of carrier tape 72 engage with the tooth portion of sprocket 64 (step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (step S6). Thus, the setup work for one feeder 60 ends. Setup device 10 determines whether the setup work for all feeders 60 has ended (step S7). When the setup work for all feeders 60 has ended (Yes in step S7), the control by setup device 10 temporarily ends. When the setup work for all feeders 60 does not end (No in Step S7), the control by setup device 10 returns to the control illustrated in Step S1, and the control described above is repeated until the setup work for all feeders 60 ends.

When the control by setup device 10 ends, for example, the worker conveys feeder accommodation section 51 accommodating feeder 60 that has been set up to the component mounter, and performs the changeover of feeder 60. When reel 70 is placed in temporary placement area 22e, reel 70 becomes usable when the worker accommodates feeder 60 applicable to reel 70 in feeder accommodation section 51. Further, reel 70 left unused in temporary placement area 22e is returned to reel holding section 31 by reel transfer mechanism 40 and retrieved by the worker. Further, the conveyance work described above by the worker can also be automated using a known automated guided vehicle or the like.

### 1-3. Configuration Example of Fastening Tape Peeling Device 80

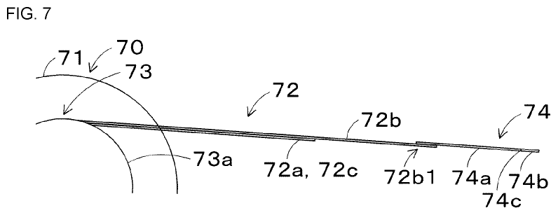

As illustrated in FIG. 3, carrier tape 72 is spirally wound around reel 70. As illustrated in FIG. 7, for example, the tip end side of carrier tape 72 of unused reel 70 is formed such that cover tape 72b protrudes from base tape 72a. Tip end portion 72b1 of cover tape 72b and outer peripheral portion 73a of spiral tape 73 are fastened by fastening tape 74.

FIG. 7 is a schematic view of reel 70 as viewed in the rotation axis direction, and illustrates a state, in which fastening tape 74 has been peeled from outer peripheral portion 73a of spiral tape 73 and the tip end side of carrier tape 72 is extended, for convenience of description. As described above, with respect to reel 70 in use, a process of fastening carrier tape 72 is performed. In this case, similarly to unused reel 70, the tip end side of carrier tape 72 can be fastened by fastening tape 74.

As described above, when reel 70 in which the tip end side of carrier tape 72 is fastened by fastening tape 74 is set in feeder 60, it is necessary to peel fastening tape 74. When a worker performs the peeling of fastening tape 74, the number of work steps of the worker increases. Here, in the embodiment, fastening tape peeling device 80 is provided. Fastening tape peeling device 80 peels fastening tape 74 of reel 70.

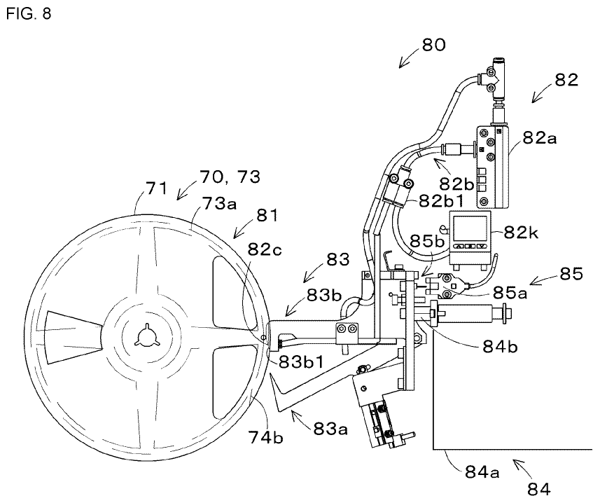

Specifically, fastening tape peeling device 80 includes support mechanism 81, separating mechanism 82, gripping mechanism 83, and separation mechanism 84. Fastening tape peeling device 80 may include outer peripheral portion detection section 85. As shown in FIG. 8, fastening tape peeling device 80 of the embodiment includes support mechanism 81, separating mechanism 82, gripping mechanism 83, separation mechanism 84, outer peripheral portion detection section 85.

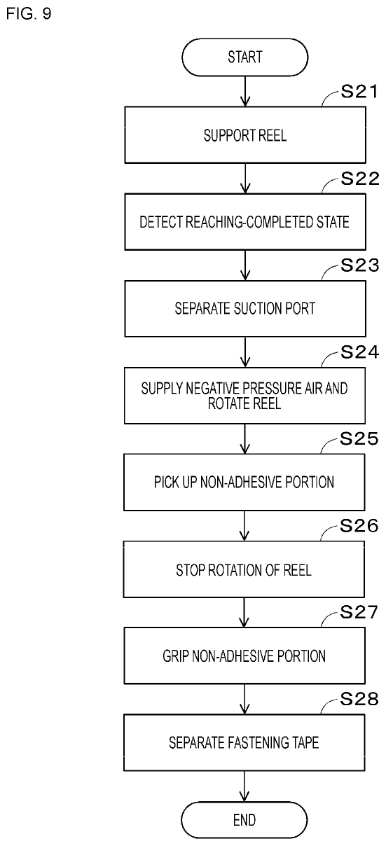

Fastening tape peeling device 80 of the embodiment performs control according to the flowchart illustrated in FIG. 9. Support mechanism 81 performs the process shown in step S21. Separating mechanism 82 performs the processes shown in steps S23 to S26. Gripping mechanism 83 performs the process shown in step S27. Separation mechanism 84 performs the process shown in step S28. Outer peripheral portion detection section 85 performs the process shown in step S22. The matters described in the present description can be appropriately selected and applied. Further, the matters described in the present description can be appropriately combined.

As described above, in carrier tape 72, cover tape 72b that closes accommodation section 72d is attached to base tape 72a provided with accommodation section 72d that accommodates component 91. Support mechanism 81 rotatably supports reel 70 on which outer peripheral portion 73a of spiral tape 73, around which carrier tape 72 is spirally wound, and tip end portion 72b1 of cover tape 72b are fastened by fastening tape 74 (step S21).

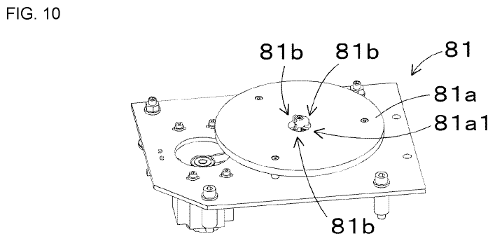

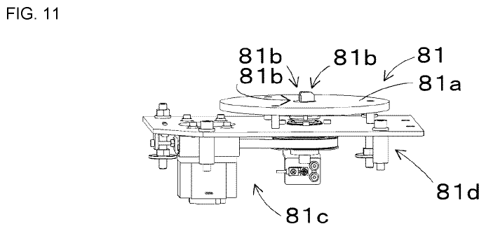

Support mechanism 81 need only rotatably support reel 70 described above, and may take various configurations. For example, as illustrated in FIGS. 10 and 11, support mechanism 81 includes placement section 81a, multiple (for example, three) claw portions 81b, drive section 81c, and reel detection section 81d. Placement section 81a is formed in a circular plate shape equivalent to the diameter of reel 70, and reel 70 described above is placed.

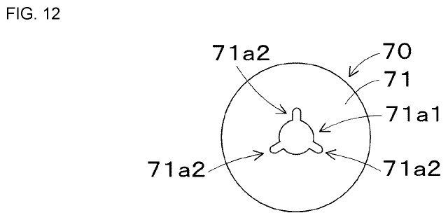

Placement section side hole portion 81a1 is formed in the center of placement section 81a such that multiple (three) claw portions 81b can protrude. Placement section side hole portion 81a1 is formed to be slightly larger than reel side hole portion 71a1 formed in the center of main body portion 71 of reel 70. As illustrated in FIG. 12, multiple (for example, three) groove portions 71a2 extending radially from the rotation axis (the center of main body portion 71) of reel 70 are formed in reel side hole portion 71a1.

Multiple (three) groove portions 71a2 are disposed at equal intervals (in this case, at positions rotated by 120° each) as viewed in the rotation axis direction of reel 70. Multiple (three) claw portions 81b are provided in accordance with the disposition of multiple (three) groove portions 71a2. Accordingly, when reel 70 is placed on placement section 81a, multiple (three) claw portions 81b can be fitted to multiple (three) groove portions 71a2.

Multiple (three) claw portions 81b are connected to the drive shaft of drive section 81c. Drive section 81c need only rotate the drive shaft, and may take various configurations. In the embodiment, a known belt drive device is used for drive section 81c. Drive section 81c rotates multiple (three) claw portions 81b connected to the drive shaft by rotating the drive shaft. When multiple (three) claw portions 81b rotate, reel 70 placed on placement section 81a rotates.

Reel detection section 81d detects whether reel 70 is appropriately placed on placement section 81a. When reel 70 is appropriately placed on placement section 81a, multiple (three) claw portions 81b are fitted to multiple (three) groove portions 71a2. Conversely, when reel 70 is not appropriately placed on placement section 81a, the fitting described above is not sufficient, and reel 70 is lifted from placement section 81a. Reel detection section 81d can detect the lifting described above.

In the embodiment, reel detection section 81d includes a detection device positioned at a predetermined distance above from the height position of reel 70 that is appropriately placed on placement section 81a. For example, the detection device emits detection light in the horizontal direction toward the upper side of reel 70. When reel 70 is appropriately placed on placement section 81a, the detection light is not blocked, and reel detection section 81d detects that reel 70 is appropriately placed on placement section 81a (there is no lifting described above). Conversely, when reel 70 is not appropriately placed on placement section 81a, the detection light is blocked, and reel detection section 81d detects that reel 70 is not appropriately placed on placement section 81a (there is the lifting described above). Reel detection section 81d can also check the front and back of reel 70 by reading the identification code attached to reel 70.

When an adhesive is provided over the entire surface of fastening tape 74 on the side fastened to outer peripheral portion 73a of spiral tape 73, it is difficult to peel fastening tape 74. Therefore, as illustrated in FIG. 7, fastening tape 74 includes adhesive portion 74a and non-adhesive portion 74b. Adhesive portion 74a is a portion where an adhesive is provided. The adhesive is provided on a portion on the base end side of fastening tape 74 on the surface of fastening tape 74 on the side fastened to outer peripheral portion 73a of spiral tape 73.

Adhesive portion 74a fastens tip end portion 72b1 of cover tape 72b and fastening tape 74. Adhesive portion 74a fastens outer peripheral portion 73a of spiral tape 73 and fastening tape 74. Non-adhesive portion 74b is a portion on the tip end side of fastening tape 74, and is a portion where the adhesive to fasten fastening tape 74 and outer peripheral portion 73a of spiral tape 73 is not provided. Since non-adhesive portion 74b is not provided with an adhesive, non-adhesive portion 74b is not fastened to outer peripheral portion 73a of spiral tape 73 and can be gripped.

Therefore, as illustrated in FIG. 8, it is assumed that non-adhesive portion 74b is gripped by gripping mechanism 83. Gripping mechanism 83 need only grip non-adhesive portion 74b, and may take various configurations. For example, gripping mechanism 83 of the embodiment includes first claw portion 83a and second claw portion 83b. First claw portion 83a is a claw-shaped portion that can enter between outer peripheral portion 73a of spiral tape 73 and non-adhesive portion 74b. Second claw portion 83b is a claw-shaped portion capable of clamping non-adhesive portion 74b together with first claw portion 83a. First claw portion 83a can move in a direction toward or away from second claw portion 83b, and when first claw portion 83a is closest to second claw portion 83b, first claw portion 83a can clamp non-adhesive portion 74b together with second claw portion 83b.

At the timing when gripping mechanism 83 grips non-adhesive portion 74b, second claw portion 83b needs to be disposed in the vicinity of outer peripheral portion 73a of spiral tape 73, and fastening tape peeling device 80 needs to detect outer peripheral portion 73a of spiral tape 73. However, outer peripheral portion 73a of spiral tape 73 has a step corresponding to the thickness of carrier tape 72, and outer peripheral portion 73a of spiral tape 73 may be erroneously detected. In addition, when reel 70 rotates in a state where second claw portion 83b presses outer peripheral portion 73a of spiral tape 73 toward the center of reel 70, carrier tape 72 on outer peripheral portion 73a may be inclined due to the pressing by second claw portion 83b.

For example, in base tape 72a to which cover tape 72b is attached, the inclination of carrier tape 72 is likely to occur in embossed type of carrier tape 72 in which accommodation section 72d protrudes. When carrier tape 72 is inclined, second claw portion 83b can move further toward the center of reel 70 from the original position of outer peripheral portion 73a of spiral tape 73, and outer peripheral portion 73a of spiral tape 73 may be erroneously detected. Further, for example, when outer peripheral portion 73a of spiral tape 73 is detected using a height sensor using a laser beam or the like, outer peripheral portion 73a of spiral tape 73 may be erroneously detected depending on the type of carrier tape 72. For example, transparent carrier tape 72 is more likely to transmit the laser beam than white or black carrier tape 72, and outer peripheral portion 73a of spiral tape 73 may be erroneously detected.

Therefore, fastening tape peeling device 80 includes separating mechanism 82. Separating mechanism 82 separates non-adhesive portion 74b of fastening tape 74 from outer peripheral portion 73a of spiral tape 73 using air. Gripping mechanism 83 grips non-adhesive portion 74b separated from outer peripheral portion 73a of spiral tape 73 by separating mechanism 82. Separating mechanism 82 need only separate non-adhesive portion 74b from outer peripheral portion 73a of spiral tape 73 using air, and may take various configurations. For example, as illustrated in FIG. 8, separating mechanism 82 can separate non-adhesive portion 74b from outer peripheral portion 73a of spiral tape 73 by picking up non-adhesive portion 74b by suction using negative pressure air.

For example, separating mechanism 82 includes air generator 82a, negative pressure supply section 82b, and suction port 82c. Air generator 82a is an air source that generates negative pressure air, positive pressure air, and the like. Negative pressure supply section 82b supplies the negative pressure air generated by air generator 82a to suction port 82c. For example, negative pressure supply section 82b includes an air pipe that communicates with suction port 82c from air generator 82a via branching device 82b1, and can supply the negative pressure air from air generator 82a to suction port 82c. Suction port 82c is a portion capable of picking up non-adhesive portion 74b by suction using negative pressure air. Suction port 82c need only be capable of picking up non-adhesive portion 74b by suction and can be provided in any member.

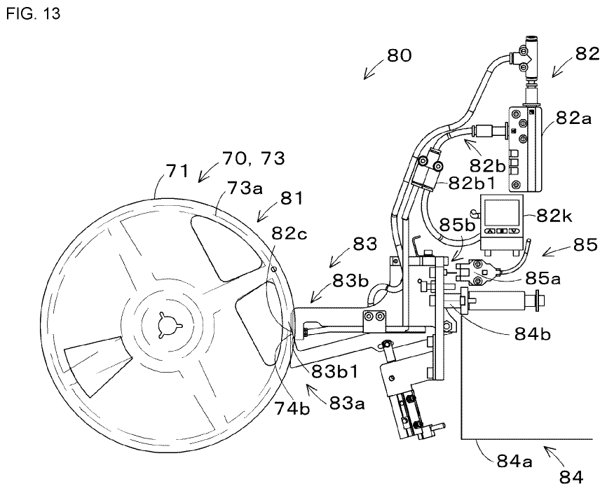

Gripping mechanism 83 of the embodiment includes first claw portion 83a and second claw portion 83b. Since gripping mechanism 83 of the embodiment is a clamp mechanism in which first claw portion 83a is movable with respect to second claw portion 83b, suction port 82c of the embodiment is provided in second claw portion 83b on the fastened side. Specifically, as illustrated in FIGS. 8 and 13, suction port 82c is provided on contact surface 83b1 of second claw portion 83b that comes into contact with non-adhesive portion 74b when non-adhesive portion 74b is clamped by first claw portion 83a and second claw portion 83b. Contact surface 83b1 is inclined at a predetermined angle with respect to the moving direction of gripping mechanism 83 (the left-right direction of the paper surface in FIGS. 8 and 13) to facilitate clamping of non-adhesive portion 74b. At least one suction port 82c may be provided on contact surface 83b1, and for example, multiple suction ports 82c may be provided along contact surface 83b1.

As described above, when reel 70 is rotated in a state where second claw portion 83b presses outer peripheral portion 73a of spiral tape 73 toward the center of reel 70, outer peripheral portion 73a of spiral tape 73 may be erroneously detected. Therefore, separating mechanism 82, in a state where suction port 82c is separated from outer peripheral portion 73a of spiral tape 73 by a predetermined distance, supplies the negative pressure air from suction port 82c while causing reel 70 to be rotated by support mechanism 81, to pick up non-adhesive portion 74b by suction at suction port 82c.

For example, fastening tape peeling device 80 may include outer peripheral portion detection section 85. Outer peripheral portion detection section 85 detects a reaching-completed state in which second claw portion 83b has reached outer peripheral portion 73a of spiral tape 73 (step S22). Outer peripheral portion detection section 85 need only detect the reaching-completed state, and may take various configurations. As shown in FIG. 8, for example, outer peripheral portion detection section 85 of the embodiment includes dog 85a and reach sensor 85b. Dog 85a is displaced when second claw portion 83b moves toward outer peripheral portion 73a of spiral tape 73 and reaches outer peripheral portion 73a of spiral tape 73. Reach sensor 85b detects a reaching-completed state in which second claw portion 83b has reached outer peripheral portion 73a of spiral tape 73 due to the displacement of dog 85a.

For example, outer peripheral portion detection section 85 moves gripping mechanism 83 toward reel 70 using separation mechanism 84 described later. As illustrated in FIG. 8, gripping mechanism 83 is supported by moving body 84a of separation mechanism 84 via elastic member 84b. Elastic member 84b is formed by, for example, a spring. When gripping mechanism 83 moves toward outer peripheral portion 73a of spiral tape 73 together with moving body 84a, second claw portion 83b of gripping mechanism 83 reaches outer peripheral portion 73a of spiral tape 73, and moving body 84a further moves, gripping mechanism 83 relatively displaces with respect to moving body 84a.

More specifically, when moving body 84a further moves toward spiral tape 73 after second claw portion 83b has reached outer peripheral portion 73a of spiral tape 73, elastic member 84b contracts against the elastic force, and gripping mechanism 83 relatively displaces with respect to moving body 84a. When elastic member 84b contracts, reach sensor 85b provided on gripping mechanism 83 side moves toward dog 85a provided on moving body 84a side, and the detection light of reach sensor 85b is blocked. Accordingly, outer peripheral portion detection section 85 can detect the reaching-completed state in which second claw portion 83b has reached outer peripheral portion 73a of spiral tape 73.

Separation mechanism 84 moves gripping mechanism 83 in the direction toward reel 70, and when reach sensor 85b detects the reaching-completed state, separation mechanism 84 moves gripping mechanism 83 in a direction away from reel 70 to separate suction port 82c from outer peripheral portion 73a of spiral tape 73 by a predetermined distance (step S23). Similarly to the case of moving gripping mechanism 83 in the direction toward reel 70, separation mechanism 84 can move gripping mechanism 83 in the direction away from reel 70 by moving moving body 84a in the direction away from reel 70.

The predetermined distance need only be such that, when reel 70 is rotated by support mechanism 81, second claw portion 83b does not interfere with carrier tape 72 and suction port 82c can pick up non-adhesive portion 74b by suction, and is not limited thereto. For example, as described above, outer peripheral portion 73a of spiral tape 73 has a step corresponding to the thickness of carrier tape 72. Therefore, the predetermined distance can be set to a distance greater than at least the thickness of carrier tape 72 and separated from outer peripheral portion 73a of spiral tape 73.

Separating mechanism 82, in a state where suction port 82c is separated from outer peripheral portion 73a of spiral tape 73 by a predetermined distance, supplies the negative pressure air from suction port 82c while causing reel 70 to be rotated by support mechanism 81, to pick up non-adhesive portion 74b by suction at suction port 82c (step S24 and step S25). In the example of reel 70 shown in FIG. 8, support mechanism 81 rotates reel 70 counterclockwise in a top view of the paper surface. Accordingly, non-adhesive portion 74b approaches suction port 82c, and suction port 82c can pick up non-adhesive portion 74b by suction.

When suction port 82c picks up non-adhesive portion 74b by suction, it is necessary to stop the rotation of reel 70. Separating mechanism 82 of the embodiment includes suction detection section 82k that detects a suction pickup completion state in which non-adhesive portion 74b is pick up by suction at suction port 82c. Suction detection section 82k need only detect the suction pickup completion state, and may take various configurations. For example, when suction port 82c picks up non-adhesive portion 74b by suction, the pressure of the negative pressure air rapidly increases. In addition, when suction port 82c picks up non-adhesive portion 74b by suction, the flow rate of the negative pressure air rapidly decreases. Therefore, suction detection section 82k can detect the suction pickup completion state using a pressure sensor that detects the pressure of the negative pressure air or a flow rate sensor that detects the flow rate of the negative pressure air.

Specifically, suction detection section 82k can detect the suction pickup completion state when the pressure of the negative pressure air exceeds a predetermined threshold or when the flow rate of the negative pressure air becomes smaller than a predetermined threshold. Suction detection section 82k can also detect the suction pickup completion state when the change amount per unit time in the pressure or flow rate of the negative pressure air exceeds a predetermined threshold. As illustrated in FIG. 8, suction detection section 82k of the embodiment detects the suction pickup completion state using the pressure sensor that detects the pressure of the negative pressure air. Specifically, suction detection section 82k is connected to branching device 82b1 of negative pressure supply section 82b, and can detect the pressure of the negative pressure air flowing through negative pressure supply section 82b. Support mechanism 81 stops the rotation of reel 70 when the suction pickup completion state is detected by suction detection section 82k (step S26).

Gripping mechanism 83 grips non-adhesive portion 74b separated from outer peripheral portion 73a of spiral tape 73 by separating mechanism 82 (step S27). Gripping mechanism 83 need only grip non-adhesive portion 74b, and may take various configurations. As described above, gripping mechanism 83 of the embodiment includes first claw portion 83a and second claw portion 83b. As illustrated in FIG. 13, when non-adhesive portion 74b is clamped by first claw portion 83a and second claw portion 83b, gripping mechanism 83 grips non-adhesive portion 74b. When non-adhesive portion 74b is gripped by gripping mechanism 83, separating mechanism 82 stops the supply of the negative pressure air.

Separation mechanism 84 separates fastening tape 74 from cover tape 72b by moving gripping mechanism 83 in the direction away from reel 70 in a state where gripping mechanism 83 grips non-adhesive portion 74b (step S28). Specifically, separation mechanism 84 includes a drive section. Drive section need only move gripping mechanism 83 as described above, and may take various configurations. As the drive section, for example, a known belt drive device can be used. The drive section can move gripping mechanism 83 as described above by moving moving body 84a as described above.

Specifically, the drive section can move moving body 84a in the direction away from reel 70 (right direction of the paper surface in FIG. 13) to move gripping mechanism 83 in the same direction. As a result, fastening tape 74 is separated from cover tape 72b. In addition, the drive section can move moving body 84a in the direction toward reel 70 (left direction of the paper surface in FIG. 13) to move gripping mechanism 83 in the same direction.

Support mechanism 81 rotatably supports reel 70. When reel 70 is placed on placement section 81a, multiple (three) claw portions 81b are fitted to multiple (three) groove portions 71a2. In addition, multiple (three) claw portions 81b are connected to the drive shaft of drive section 81c. Therefore, when separation mechanism 84 moves gripping mechanism 83 in the direction away from reel 70, resistance may be generated in the rotation of reel 70. As the resistance increases, carrier tape 72 is more likely to be broken when gripping mechanism 83 moves.

Therefore, support mechanism 81 may set the rotation amount of reel 70 in accordance with the movement amount of gripping mechanism 83 such that carrier tape 72 is not broken when gripping mechanism 83 moves in the direction away from reel 70 by separation mechanism 84 in a state where gripping mechanism 83 grips non-adhesive portion 74b. For example, as described above, gripping mechanism 83 of the embodiment includes first claw portion 83a and second claw portion 83b. In addition, fastening tape peeling device 80 includes outer peripheral portion detection section 85 including dog 85a and reach sensor 85b. In this embodiment, support mechanism 81 can estimate the diameter of spiral tape 73 based on the position of second claw portion 83b when the reaching-completed state has been detected by reach sensor 85b, and can set the rotation amount of reel 70 based on the estimated diameter of spiral tape 73.

Specifically, the drive section of separation mechanism 84 includes, for example, a position detector such as an encoder. The position detector can detect a distance between the center position of reel 70 supported by support mechanism 81 and the position of second claw portion 83b when the reaching-completed state is detected by reach sensor 85b. The distance corresponds to the radius of spiral tape 73. Accordingly, support mechanism 81 can estimate the diameter of spiral tape 73 based on the distance detected by the position detector.

Support mechanism 81 sets the rotation amount of reel 70 based on the estimated diameter of spiral tape 73. Specifically, support mechanism 81 calculates the length (circumference) of outer peripheral portion 73a of spiral tape 73 from the diameter of spiral tape 73. The length of outer peripheral portion 73a is a value obtained by multiplying the diameter of spiral tape 73 by pi. Accordingly, support mechanism 81 can recognize the pulled-out amount of carrier tape 72 per unit rotation amount of reel 70. Support mechanism 81 acquires the pulled-out amount of carrier tape 72 from the movement amount of gripping mechanism 83, and sets the rotation amount of reel 70 in accordance with the pulled-out amount of carrier tape 72. It should be noted that when the drive shaft of drive section 81c of support mechanism 81 can be separated, the drive shaft of drive section 81c may be separated.

### 1-4. Another Configuration Example of Fastening Tape Peeling Device 80

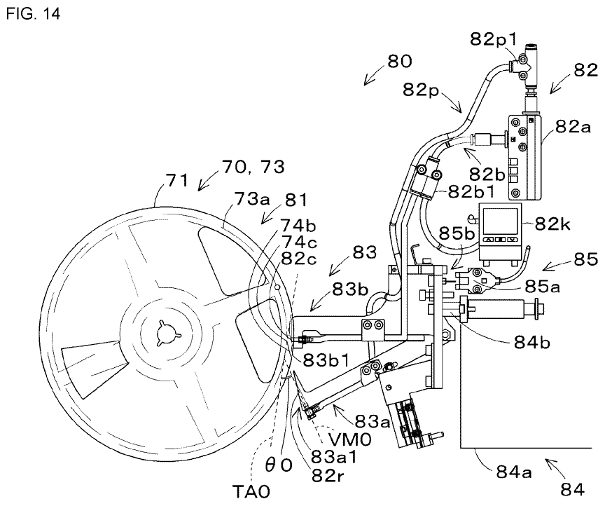

Separating mechanism 82 can also separate non-adhesive portion 74b from outer peripheral portion 73a of spiral tape 73 by blowing non-adhesive portion 74b using positive pressure air. For example, as illustrated in FIG. 14, separating mechanism 82 may include air generator 82a, positive pressure supply section 82p, and discharge port 82r. In this case, air generator 82a generates the positive pressure air. Air generator 82a can also supply the positive pressure air from the negative pressure air. Positive pressure supply section 82p supplies the positive pressure air generated by air generator 82a to discharge port 82r.

For example, positive pressure supply section 82p includes an air pipe that communicates with discharge port 82r from air generator 82a via branching device 82p1, and can supply the positive pressure air from air generator 82a to discharge port 82r. Discharge port 82r is a portion capable of discharging the positive pressure air to non-adhesive portion 74b. Discharge port 82r need only be capable of discharging the positive pressure air to non-adhesive portion 74b and can be provided in any member.

In the embodiment described above as well, gripping mechanism 83 can include first claw portion 83a and second claw portion 83b. As described above, first claw portion 83a can enter between outer peripheral portion 73a of spiral tape 73 and non-adhesive portion 74b. Therefore, discharge port 82r can be provided, for example, in first claw portion 83a on the movable side. Specifically, as illustrated in FIG. 14, discharge port 82r is provided in portion 83a1 of first claw portion 83a that can supply the positive pressure air along outer peripheral portion 73a of spiral tape 73. At least one discharge port 82r may be provided in portion 83a1, or multiple discharge ports 82r may be provided in portion 83a1.

One discharge port 82r illustrated in FIG. 14 is provided at portion 83a1 of first claw portion 83a. Further, in discharge port 82r, angle θ0 formed by tangent line TAO of outer peripheral portion 73a of spiral tape 73 at boundary portion 74c between adhesive portion 74a and non-adhesive portion 74b illustrated in FIGS. 7 and 14 and discharge direction VM0 of the positive pressure air is set to an acute angle smaller than 90 degrees. Therefore, the positive pressure air discharged from discharge port 82r can flow toward non-adhesive portion 74b along outer peripheral portion 73a of spiral tape 73 at the timing when non-adhesive portion 74b is clamped by first claw portion 83a and second claw portion 83b. As a result, non-adhesive portion 74b is blown by the positive pressure air, and non-adhesive portion 74b can be separated from outer peripheral portion 73a of spiral tape 73.

In the same manner as when non-adhesive portion 74b is pick up by suction using negative pressure air, separating mechanism 82 can separate non-adhesive portion 74b from outer peripheral portion 73a of spiral tape 73. Specifically, separating mechanism 82, in a state where discharge port 82r is separated from outer peripheral portion 73a of spiral tape 73 by a predetermined distance, supplies the positive pressure air from discharge port 82r while causing reel 70 to be rotated by support mechanism 81, to separate non-adhesive portion 74b from outer peripheral portion 73a of spiral tape 73. In addition, fastening tape peeling device 80 can include outer peripheral portion detection section 85 including dog 85a and reach sensor 85b. In this case, separation mechanism 84 can move gripping mechanism 83 in the direction toward reel 70, and when reach sensor 85b detects the reaching-completed state, separation mechanism 84 can move gripping mechanism 83 in a direction away from reel 70 to separate discharge port 82r from outer peripheral portion 73a of spiral tape 73 by a predetermined distance.

Gripping mechanism 83 can grip non-adhesive portion 74b separated from outer peripheral portion 73a of spiral tape 73 by separating mechanism 82. In addition, support mechanism 81 can detect that non-adhesive portion 74b is gripped by gripping mechanism 83 using various detection devices. For example, the gripping of non-adhesive portion 74b by gripping mechanism 83 can be detected by performing image processing on an image captured by the imaging device. When the gripping of non-adhesive portion 74b by gripping mechanism 83 is detected, support mechanism 81 stops the rotation of reel 70. Further, positive pressure supply section 82p stops the supply of the positive pressure air. Then, separation mechanism 84 can separate fastening tape 74 from cover tape 72b by moving gripping mechanism 83 in the direction away from reel 70 in a state where gripping mechanism 83 grips non-adhesive portion 74b.

For example, non-adhesive portion 74b is attached to outer peripheral portion 73a of spiral tape 73 due to static electricity or the like. In such a case, it may be difficult to separate non-adhesive portion 74b from outer peripheral portion 73a of spiral tape 73 by picking up non-adhesive portion 74b by suction using negative pressure air alone. In addition, it may be difficult for gripping mechanism 83 to grip non-adhesive portion 74b only by blowing non-adhesive portion 74b using positive pressure air. Therefore, as illustrated in FIG. 14, separating mechanism 82 can also separate non-adhesive portion 74b from outer peripheral portion 73a of spiral tape 73 by blowing non-adhesive portion 74b using positive pressure air and picking up non-adhesive portion 74b by suction using negative pressure air. For example, in this embodiment, support mechanism 81 can stop the rotation of reel 70 when the suction pickup completion state is detected by suction detection section 82k. As described above, the embodiments described above are combinations of the embodiments described above, and the matters described above can be appropriately selected and applied.

Fastening tape peeling device 80 can be provided at any position inside or outside setup device 10. For example, fastening tape peeling device 80 can be provided near tape loading mechanism 23 and reel transfer mechanism 40 (for example, placement area 22d, or the like). Placement of reel 70 on placement section 81a of support mechanism 81 may be performed by the worker or may be performed by reel transfer mechanism 40, or the like. Further, reel 70 from which fastening tape 74 has been peeled by fastening tape peeling device 80 may be attached to feeder 60 by the worker, or may be attached to feeder 60 by tape loading mechanism 23.

### 2. Example of Effect of Embodiment

According to fastening tape peeling device 80, it is possible to separate non-adhesive portion 74b from outer peripheral portion 73a of spiral tape 73 using air and grip separated non-adhesive portion 74b to peel fastening tape 74.

### REFERENCE SIGNS LIST

70: Reel, 72: Carrier tape, 72a: Base tape,
72b: Cover tape, 72b1: Tip end portion, 72d: Accommodation section,
73: Spiral tape, 73a: Outer peripheral portion, 74: Fastening tape,
74b: Non-adhesive portion, 80: Fastening tape peeling device, 81: Support mechanism,
82: Separating mechanism, 82c: Suction port, 82k: Suction detection section,
82r: Discharge port, 83: Gripping mechanism, 83a: First claw portion,
83a1: Portion, 83b: Second claw portion, 83b1: Contact surface,
84: Separation mechanism, 85: Outer peripheral portion detection section, 85a: Dog,
85b: Reach sensor, 91: Component.

1. A fastening tape peeling device comprising:
a support mechanism configured to rotatably support a reel in which an outer peripheral portion of a spiral tape and a tip end portion of the cover tape are fastened by a fastening tape, a carrier tape being spirally wound in the spiral tape, the carrier tape including a base tape provided with an accommodation section that accommodates a component, and a cover tape that closes an accommodation section and is attached to the base tape;
a separating mechanism configured to separate, from the outer peripheral portion of the spiral tape using air, a non-adhesive portion which is a portion on a tip end side of the fastening tape of the reel supported by the support mechanism and in which an adhesive for fastening the fastening tape and the outer peripheral portion of the spiral tape is not provided;
a gripping mechanism configured to grip the non-adhesive portion separated from the outer peripheral portion of the spiral tape by the separating mechanism; and
a separation mechanism configured to separate the fastening tape from the cover tape by moving the gripping mechanism in a direction away from the reel in a state where the gripping mechanism grips the non-adhesive portion.

2. The fastening tape peeling device according to claim 1, wherein the separating mechanism separates the non-adhesive portion from the outer peripheral portion of the spiral tape by picking up the non-adhesive portion by suction using negative pressure air.

3. The fastening tape peeling device according to claim 2, wherein the separating mechanism, in a state where a suction port configured to pick up the non-adhesive portion by suction using the negative pressure air is separated from the outer peripheral portion of the spiral tape by a predetermined distance, supplies the negative pressure air from the suction port while causing the reel to be rotated by the support mechanism, to pick up the non-adhesive portion by suction at the suction port.

4. The fastening tape peeling device according to claim 3,
wherein the gripping mechanism includes
a first claw portion configured to enter between the outer peripheral portion of the spiral tape and the non-adhesive portion, and
a second claw portion configured to clamp the non-adhesive portion between the first claw portion and the second claw portion, and
the suction port is provided on a contact surface of the second claw portion configured to come into contact with the non-adhesive portion when the non-adhesive portion is clamped by the first claw portion and the second claw portion.

5. The fastening tape peeling device according to claim 4, further comprising:
an outer peripheral portion detection section including
a dog that is displaced when the second claw portion moves toward the outer peripheral portion of the spiral tape and reaches the outer peripheral portion of the spiral tape, and
a reach sensor configured to detect a reaching-completed state in which the second claw portion has reached the outer peripheral portion of the spiral tape due to the displacement of the dog,
wherein the separation mechanism moves the gripping mechanism in a direction toward the reel, and when the reaching-completed state is detected by the reach sensor, moves the gripping mechanism in a direction away from the reel to separate the suction port from the outer peripheral portion of the spiral tape by the predetermined distance.

6. The fastening tape peeling device according to claim 3,
wherein the separating mechanism includes a suction detection section configured to detect a suction pickup completion state in which the non-adhesive portion is pick up by suction at the suction port, and
the support mechanism stops the rotation of the reel when the suction pickup completion state is detected by the suction detection section.

7. The fastening tape peeling device according to claim 6, wherein the suction detection section detects the suction pickup completion state using a pressure sensor configured to detect a pressure of the negative pressure air or a flow rate sensor configured to detect a flow rate of the negative pressure air.

8. The fastening tape peeling device according to claim 1, wherein the separating mechanism separates the non-adhesive portion from the outer peripheral portion of the spiral tape by blowing the non-adhesive portion using positive pressure air.

9. The fastening tape peeling device according to claim 8, wherein the separating mechanism, in a state where a discharge port configured to discharge the positive pressure air to the non-adhesive portion is separated from the outer peripheral portion of the spiral tape by a predetermined distance, supplies the positive pressure air from the discharge port while causing the reel to be rotated by the support mechanism, to separate the non-adhesive portion from the outer peripheral portion of the spiral tape.

10. The fastening tape peeling device according to claim 9,
wherein the gripping mechanism includes
a first claw portion configured to enter between the outer peripheral portion of the spiral tape and the non-adhesive portion, and
a second claw portion configured to clamp the non-adhesive portion between the first claw portion and the second claw portion, and
the discharge port is provided in a portion of the first claw portion configured to supply the positive pressure air along the outer peripheral portion of the spiral tape.

11. The fastening tape peeling device according to claim 1, wherein the support mechanism sets a rotation amount of the reel in accordance with a movement amount of the gripping mechanism such that the carrier tape is not broken when the gripping mechanism moves in a direction away from the reel by the separation mechanism in a state where the gripping mechanism grips the non-adhesive portion.

12. The fastening tape peeling device according to claim 11,
wherein the gripping mechanism includes:
a first claw portion configured to enter between the outer peripheral portion of the spiral tape and the non-adhesive portion; and
a second claw portion configured to clamp the non-adhesive portion between the first claw portion and the second claw portion,
the fastening tape peeling device comprises
an outer peripheral portion detection section including:
a dog that is displaced when the second claw portion moves toward the outer peripheral portion of the spiral tape and reaches the outer peripheral portion of the spiral tape; and
a reach sensor configured to detect a reaching-completed state in which the second claw portion has reached the outer peripheral portion of the spiral tape due to the displacement of the dog, and
the support mechanism estimates a diameter of the spiral tape based on a position of the second claw portion when the reaching-completed state is detected by the reach sensor, and sets the rotation amount of the reel based on the estimated diameter of the spiral tape.
